(19) United States
(12) Patent Application Publication
(10) Pub. No.: US 2004/0125574 A1
(43) Pub. Date: Jul. 1, 2004

(54) Multi-chip semiconductor package and method for manufacturing the same

(76) Inventor: Ki-Myung Yoon, Cheonan-city (KR)

Correspondence Address: HARNESS, DICKEY & PIERCE, P.L.C., P.O. BOX 8910, RESTON, VA, 20195, US

(21) Appl. No.: 10/681,254

(22) Filed: Oct. 9, 2003

(30) Foreign Application Priority Data
Dec. 26, 2002 (KR) 2002-84242

(51) Int. Cl. H05K 7/00

(52) U.S. Cl. 361/735

(57) ABSTRACT

Provided is a multi-chip semiconductor package incorporating stacked semiconductor package structures with each package structure including a substrate, a semiconductor chip mounted on the substrate, an enclosure body formed across the entire surface of the substrate where the semiconductor chip is mounted, a plurality of conductive studs extending through the enclosure body outside the periphery of the semiconductor chip and one or more conductive members provided below the substrate and in contact with the conductive studs. During assembly of the multi-chip semiconductor package, the conductive member of an upper semiconductor package structure provides electrical contact to corresponding conductive studs on a lower semiconductor package structure.

This application claims priority under 35 U.S.C. § 119 from Korean Patent Application No. 2002-84242, filed Dec. 26, 2002, in the Korean Intellectual Property Office, the contents of which are incorporated herein by reference in its entirety.

### BACKGROUND OF THE INVENTION

1. Field of the Invention

The present invention relates to a semiconductor package and a method for manufacturing such a package. More specifically, the present invention relates to a multi-chip semiconductor package in which a plurality of chips are stacked and a method for manufacturing such a stacked chip package.

2. Description of the Related Art

In recent years, with the rapidly increasing demand for portable electronic products, the demand for thin, small and lightweight semiconductor products has also increased as has the demand for highly-integrated semiconductor memory products. These demands have been addressed by a variety of techniques for processing fine circuits to obtain devices having very high integration densities and/or reducing the area of the resulting semiconductor devices. Another alternative for increasing the effective device density involves the use of multi-chip semiconductor packages.

Multi-chip semiconductor packages are obtained by mounting two or more semiconductor chips in a single package to provide multiple functions and/or increased amounts of data storage. In particular, multi-chip semiconductor packages have been widely utilized in small lightweight cellular phones.

A conventional multi-chip semiconductor package, as illustrated in FIG. 1, incorporates two or more package structures 10a and 10b a single semiconductor package. Each of the package structures 10a and 10b includes a substrate 11 and a semiconductor chip 15 which is attached to the substrate 11. The semiconductor chip 15 may be disposed in the center of the substrate 11 with electrode pads (not shown) disposed on an upper surface adjacent the edge of the semiconductor chip 15. The electrode pads of the semiconductor chip 15 may be bonded to conductive pads or a pattern (not shown) of the substrate 11 by means of a wires 20. The semiconductor chip 15 and the wires 20 are then encapsulated in an enclosure body, which may be of epoxy molding compound (EMC) or other suitable resin.

Meanwhile, a plurality of interconnection members 30, which provide interlayer connecting paths, are formed through substrate 10 outside the periphery of the enclosure body 25. Each of the interconnection members 30 serves as a portion of a connection path for electrically connecting the upper and lower package structures 10a and 10b. The interconnection members 30 are spaced from the enclosure body 25 by a predetermined distance in order to insulate them from the semiconductor chip 15 of the other package structure. A solder ball 35 may be attached to the bottom of each of the interconnection members 30 for connecting the corresponding interconnection members of the upper and lower package structures 10a and 10b.

As illustrated in FIG. 1, the solder balls 35 provided on the upper package structure 10a are in contact with corresponding interconnection members provided on the lower package structure 10b, thereby electrically connecting the upper and lower package structures. The solder balls 35 and underlying ball pads preferably have a height (B) greater than the height of the enclosure body 25 so as to maintain a sufficient space in which the enclosure body 25 of the lower package structure 10b may be located.

As described above, in a conventional multi-chip semiconductor package the height of the solder ball 35 is typically greater than that of the enclosure body 25 in order to maintain sufficient space for the enclosure body. For this reason, the degree to which the height of the multi-chip semiconductor package can be reduced is limited. Further, because the enclosure body 25 is formed in one portion of the substrate 11, the substrate will typically require a thickness sufficient to support the weight of the enclosure body 25. The strength requirement for the substrate 11, therefore, further limits the degree to which the thickness of the package can be reduced.

Furthermore, because interconnection members 30 penetrate the substrate 11, the interconnection members must be separated and insulated from the enclosure body 25. In order to ensure sufficient spacing between the interconnection members 30 and the enclosure body 25, a misaligmnent margin (A) is typically provided. However, the use of the misalignment margin (A) increases the area of the package and/or reduces the area available for locating input/output pads.

### SUMMARY OF THE INVENTION

Exemplary embodiments of the present invention provide both multi-chip semiconductor packages providing reduced height and/or occupying a smaller area and methods for manufacturing such packages.

An exemplary embodiment of the present invention provides a multi-chip semiconductor package having stacked semiconductor package structures, each of which includes a substrate; a semiconductor chip which is electrically mounted in a predetermined portion of the substrate; an enclosure body covering the entire surface of the substrate where the semiconductor chip is mounted; a plurality of conductive studs formed through the enclosure body on both sides of the semiconductor chip; and conductive members, such as solder balls or conductive patterns, provided on the bottom of the substrate in contact with each of the conductive studs.

Exemplary embodiments of the package structures may have the same configuration so that the conductive members of a first package structure may electrically contact a corresponding conductive studs of a second package structure arranged below the first package structure. Alternatively, the conductive members of a first package structure may electrically contact corresponding conductive members provided on another package structure arranged below the first package.

Exemplary embodiments of suitable substrates may include a conductive layer and an insulating layer, such as a resin layer, attached to the bottom of the conductive layer. The semiconductor chip will typically include conductive pads and be attached to or recessed into the substrate with the conductive pads electrically connected to the conductive layer of the substrate by conductor, such as bonding wires, conductive polymers or metal patterns. Alternatively, the semiconductor chip may be bonded to the conductive layer of the substrate through conductive balls.

Meanwhile, exemplary embodiments of the substrate may also include a resin layer and a conductive layer attached to the bottom of the resin layer with an additional conductive stud formed through the resin layer and electrically connected to corresponding studs formed in the enclosure body.

Another exemplary embodiment of the present invention provides a semiconductor package comprising stacked semiconductor package structures, each of which includes a substrate having a conductive layer and an insulating layer disposed under the conductive layer; a semiconductor chip installed in a predetermined portion of the substrate; an enclosure body formed on substantially the entire surface of the substrate where the semiconductor chip is mounted; a plurality of conductive studs installed through the enclosure body on both sides of the semiconductor chip; and solder balls installed on the bottom of the substrate in electrical contact with each of the conductive studs. Conductive pads may be provided on the semiconductor chip and electrically connected to the conductive layer of the substrate by conductive wires. The solder balls may be used to establish electrical contact with the corresponding studs of a second package structure disposed below a first package structure.

Another exemplary embodiment of the present invention provides a semiconductor package comprising stacked semiconductor package structures, each of which includes a substrate, a semiconductor chip recessed in a predetermined portion of the substrate, an enclosure body covering substantially the entire surface of the semiconductor chip and the substrate, a plurality of conductive studs that extend through the enclosure body on both sides of the semiconductor chip, and conductive members installed at the bottom of the substrate to provide electrical contact to each of the conductive studs. Conductive pads are formed on the semiconductor chip and are typically electrically connected to the conductive layer of the substrate by a conductive wire. The conductive members are also typically in electrical contact with corresponding studs provided on another package structure disposed below a first package structure.

Another exemplary embodiment of the present invention provides a semiconductor package comprising a plurality of semiconductor package structures, each of which includes a substrate, a semiconductor chip that is attached to a predetermined portion of the substrate by conductive balls, an enclosure body that is formed on the entire surface of the semiconductor chip and the substrate in order to protect the semiconductor chip, a plurality of conductive studs installed through the enclosure body on both sides of the semiconductor chip, and a conductive member that is installed at the bottom of the substrate to provide electrical contact to each of the conductive studs to provide electrical contact with a corresponding stud of another package structure.

Another exemplary embodiment of the present invention provides a method for manufacturing a multi-chip semiconductor package including providing a substrate and forming a plurality of studs on both sides of the substrate, mounting a semiconductor chip, typically near the center of the substrate, between the studs and forming an enclosure body on the substrate where the semiconductor chip is mounted. The enclosure body is then ground until a surface of the studs is exposed and conductive members are formed in a portion of the bottom of the substrate in contact with corresponding studs, thereby forming a unit package structure. The package structure may then be bonded to one or more other package structures having the same configuration in a manner such that the conductive members of each package structure are in contact with a corresponding stud or a conductive member provided on an adjacent package structure. Providing the substrate includes forming a insulating layer, typically a resin layer, under the conductive layer and, before or after forming the studs, removing the portions of the resin layer corresponding to the studs.

### BRIEF DESCRIPTION OF THE DRAWINGS

The above and other features and advantages of the present invention will become more apparent in light of the detailed descriptions of exemplary embodiments with reference to the attached drawings in which:

FIG. 1 is a cross-sectional view of a conventional multi-chip semiconductor package;

FIG. 2 is a cross-sectional view of a multi-chip semiconductor package illustrating a first exemplary embodiment of the present invention;

FIG. 3 is a cross-sectional view of a multi-chip semiconductor package illustrating a second exemplary embodiment of the present invention;

FIGS. 4 and 5 are cross-sectional views of a multi-chip semiconductor package illustrating a third exemplary embodiment of the present invention;

FIG. 6 is a cross-sectional view of a multi-chip semiconductor package illustrating a fourth exemplary embodiment of the present invention;

FIGS. 7A through 7D are cross-sectional views illustrating certain process steps included in a method for manufacturing a multi-chip semiconductor package according to a fifth exemplary embodiment of the present invention; and

FIG. 8 is a plan view illustrating the relationship between the conductive layer and the associated conductive studs or conductive balls.

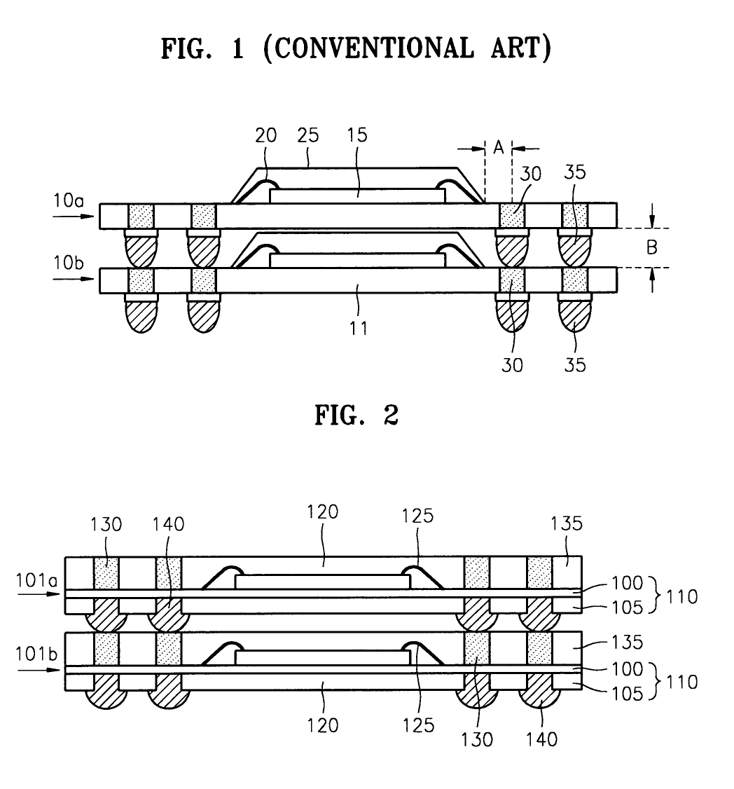

### DETAILED DESCRIPTION OF THE INVENTION

The present invention will now be described more fully with reference to the accompanying drawings, in which exemplary embodiments of the invention are shown. This invention may, however, be embodied in many different forms and should not be construed as being limited to the particular embodiments set forth herein. Rather, these exemplary embodiments are provided so that this disclosure will be thorough and complete and will fully convey the concept of the invention to those skilled in the art. In the drawings, the shape of elements is exaggerated for clarity, and the same reference numeral in different drawings represent the same element.

### FIRST EXEMPLARY EMBODIMENT

FIG. 2 is a cross-sectional view of a multi-chip semiconductor package illustrating a first exemplary embodiment of the present invention.

As illustrated in FIG. 2, the multi-chip semiconductor package of the present embodiment includes a plurality of stacked semiconductor package structures 101a and 101b that may have the same configuration. Each of the package structures 101a and 101b includes a substrate 110 and a semiconductor chip 120 which is attached near the center of the substrate. For example, the substrate 110 may include a conductive layer 100 and an insulating layer 105, such as a photo solder resist (PSR) or other resin, provided under the conductive layer 100. The semiconductor chip 120 includes a plurality of bonding pads (not shown) that may be positioned generally adjacent the edge of the semiconductor chip, with the bonding pads connected to the conductive layer 100 of the substrate 110 by wires 125.

An enclosure body 135 is formed on the entire surface of the substrate 110 where the semiconductor chip 120 is mounted and a plurality of studs 130 are formed through the enclosure body on both sides of the semiconductor chip 120. The studs 130 are used to provide electrical connections between the upper and lower packages in a multi-chip semiconductor package. As illustrated in this embodiment, both the semiconductor chip 120 and the studs 130 may be mounted within the enclosure body 135, thereby reducing the misalignment margin relative to a conventional multi-chip semiconductor package.

A solder ball 140 is installed in the insulating layer 105 corresponding to each of the studs 130 of the upper package structure 101a for providing electrical connections to the studs 130 of the lower package structure 101b. As illustrated in this exemplary embodiment, the enclosure body 135 is formed on the entire surface of the substrate 110 and the studs 130 are installed in a predetermined portion of the enclosure body 135. Thus, the solder ball 140 need not have a height greater than that of the semiconductor chip 120 (or the enclosure body 135) and the height of the multi-chip semiconductor package can be decreased accordingly.

Also, because the enclosure body 135 is formed on the entire surface of the substrate 110, the load is more evenly applied across the substrate 110 and the mechanical strength of the multi-chip semiconductor package can be improved or maintained while using a substrate having a reduced thickness.

### SECOND EXEMPLARY EMBODIMENT

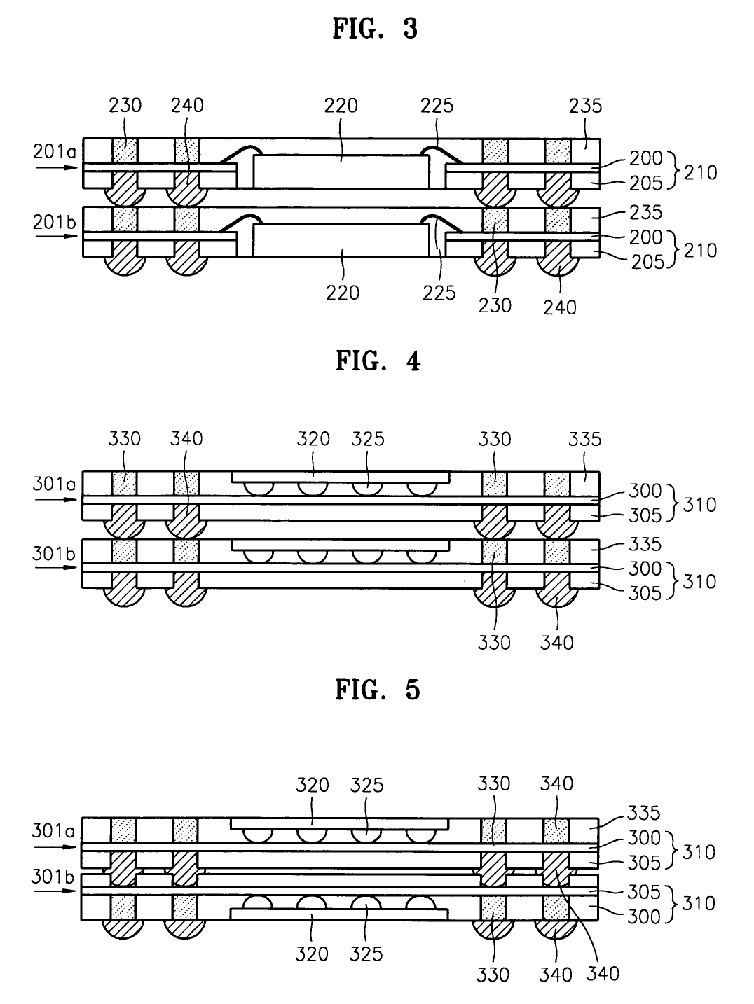

FIG. 3 is a cross-sectional view of a multi-chip semiconductor package illustrating a second exemplary embodiment of the present invention.

As illustrated in FIG. 3, the multi-chip semiconductor package of the present embodiment includes stacked semiconductor package structures 201a and 201b that may have the same configuration. Each of the package structures 201a and 201b includes a substrate 210 and a semiconductor chip 220 which is recessed near the center of the substrate 210. For example, the substrate 210 may include a conductive layer 200 and an insulating layer 205 formed from a PSR or other suitable resin formed under the conductive layer. The semiconductor chip 220 includes bonding pads (not shown) near its edge and the bonding pads are connected to the conductive layer 200 of the substrate 210 by wires 225.

Each of the package structures 201a and 201b may be formed by providing a substrate 210 having an opening formed therein. An adhesive tape (not shown) can then be applied to the lower surface of the substrate, thereby cooperating with the opening to form a recess. A semiconductor chip 220 may then be inserted into the recess and attached to the adhesive tape to position the semiconductor chip relative to the substrate 210. Electrical connections between the semiconductor chip 220 and the substrate 210 may then be formed by a process such as wire bonding. The upper surface of the substrate, semiconductor chip; and the bonding wires 225 may then be encapsulated with a resin or other suitable material to fix the relative position of the components and protect them from environmental exposure. The adhesive tape may then be removed from the lower surface of the substrate to complete the formation of the package structure.

An enclosure body 235 is formed on the entire surface of the substrate 210 where the semiconductor chip 220 is recessed, and a plurality of studs 230 are disposed in predetermined portions of the enclosure body such as, for example, on both sides of the semiconductor chip. The studs 230 are used as pads to provide electrical connection between the upper 201a and lower 201b packages in the multi-chip semiconductor package.

Solder balls 240 provided in the insulating layer 205 corresponding to each of the studs 230 of the upper package 201a are electrically connected to the corresponding studs 230 of the lower package structure 201b. According to this exemplary embodiment, the recessed semiconductor chip 220 can produce a thinner overall semiconductor device and allow the use of a substrate having a reduced mechanical strength.

### THIRD EXEMPLARY EMBODIMENT

FIG. 4 is a cross-sectional view of a multi-chip semiconductor package according to a third exemplary embodiment of the present invention that includes stacked semiconductor package structures 301a and 301b that may have the same configuration. Each of the package structures 301a and 301b includes a substrate 310 and a semiconductor chip 320 which is attached to the center of the substrate 310. For example, the substrate 310 may include a conductive layer 300 and an insulating layer 305 of a material such as a PSR or resin formed under the conductive layer. The semiconductor chip 320 may be electrically bonded to the substrate 310 through conductive balls 325.

An enclosure body 335 may then be formed on the entire surface of the substrate 310 where the semiconductor chip 320 is mounted. A plurality of studs 330 may be provided through predetermined portions of the enclosure body 335, for example, on both sides of the semiconductor chip 320. The studs 330 are used as paths for electrically connecting the upper 301a and lower 301b packages in a multi-chip semiconductor package.

Solder balls 340 installed in the insulating layer 305 and corresponding to each of the studs 330 in the upper package 301a may be used to provide electrical connections to the corresponding studs 330 of the lower package structure 301b.

This embodiment may also be adapted to a ball-grid-array (BGA)-type multi-chip semiconductor package. As illustrated in FIG. 5, the solder balls 340 of the upper package structure 301a may be attached to the solder balls 340 of the lower package structure 301b, i.e., the insulating layers 305 of the substrates 310 may be attached facing each other to reduce the thickness of the resulting semiconductor devices.

### FOURTH EXEMPLARY EMBODIMENT

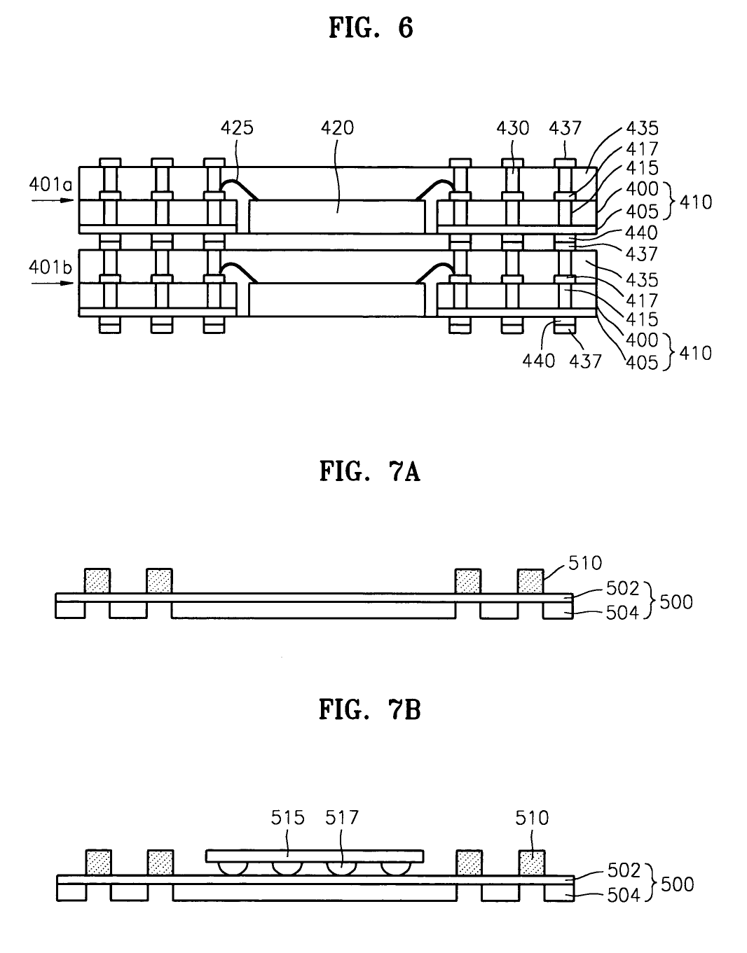

FIG. 6 is a cross-sectional view of a multi-chip semiconductor chip according to a fourth exemplary embodiment of the present invention including stacked semiconductor package structures 401a and 401b that may have the same configuration. Each of the package structures 401a and 401b includes a substrate 410 and a semiconductor chip 420 which is recessed near the center of the substrate 410.

In this exemplary embodiment, for example, the substrate 410 may include a insulating layer 400 of bismalemide-triazine (BT) resin and a conductive layer 405 which is formed under the insulating layer. In order to connect adjacent package structures, an interconnection path will typically be provided through the insulating layer 400. In this exemplary embodiment, a first stud 415 is installed in the insulating layer 400 on both sides of the semiconductor chip 420 to provide electrical connections between the upper and lower packages, and a first conductive pattern 417 is disposed on the first studs 415. The semiconductor chip 420 may also include conductive pads (not shown) at its edge that may be electrically connected to the first conductive pattern 417 by wires 425.

An enclosure body 435 may then be formed on the entire surface of the substrate 410 where the semiconductor chip 420 is recessed. Second studs 430 are provided through predetermined portions of the enclosure body 435, for example, on both sides of the semiconductor chip 420, and connected to the first conductive pattern 417. A second conductive pattern 437 may then be formed in contact with the second stud 430. The first and second conductive patterns, 417 and 437, may be formed with widths larger than the diameters of the first and the second studs, 415 and 430, and may be used as alignment subsidiary patterns.

Meanwhile, a third conductive pattern 440 may be provided on the bottom of the conductive layer 405 of the substrate 410 corresponding to the first studs 415. The third conductive pattern 440, in turn, is in electrical contact with the second conductive pattern of the lower package structure 401b.

As described above, the substrate 410 may be formed from a stack of an insulating layer 400 of, for example a BT resin, and a conductive layer 405, with first and second studs 415 and 430 provided in the substrate 410 and the enclosure body 435, respectively. Thus, the multi-chip semiconductor package according to this exemplary embodiment can be manufactured without requiring the use of solder balls having heights greater than the enclosure body 435. Indeed, the first and second conductive patterns 417 and 437 may be used as an alternative to solder balls, thereby allowing the production of semiconductor devices having reduced thicknesses.

### FIFTH EXEMPLARY EMBODIMENT

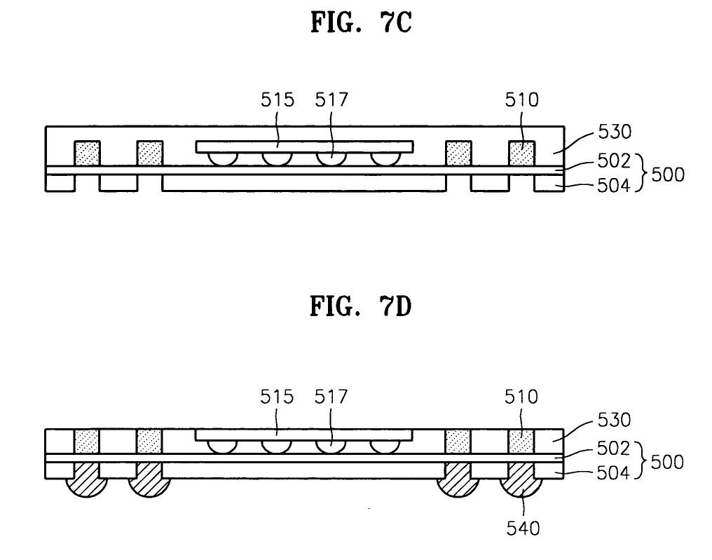

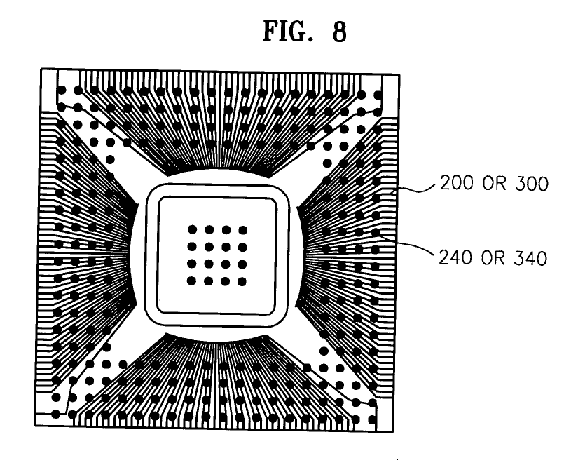

FIGS. 7A through 7D are cross-sectional views illustrating an exemplary method for manufacturing a multi-chip semiconductor package according to an exemplary embodiment of the present invention. As illustrated in FIG. 7A, a substrate 500 for mounting a semiconductor chip may be formed from a stack of a conductive layer 502 and an insulating layer 504 of, for example a PSR or other suitable resin, provided on the side of the conductive layer 502 opposite the semiconductor chip. A layer of a conductive material may then be formed on the conductive layer 502, patterned and etched to form a plurality of studs 510 on the conductive layer 502. Next, portions of the insulating layer 504 corresponding to the studs 510 is removed from the opposite side of the conductive layer 502 by a conventional method for patterning and etching insulating materials such as resins.

Referring to FIG. 7B, a semiconductor chip 515 is mounted near the center of substrate 500, i.e., on the conductive layer 502 between the studs 510 disposed around the mounting location. The semiconductor chip 515 may be attached to the conductive layer 502 using a plurality of conductive balls 517 or by conventional wire bonding techniques.

As illustrated in FIG. 7C, an enclosure body 530 may then be formed on the substrate 500. The enclosure body 530 is typically formed to a thickness sufficient to enclose both the studs 510 and the semiconductor chip 515. Then, as illustrated in FIG. 7D, an upper portion of the enclosure body 530 is removed, typically by grinding, to expose the surface of the studs 510 and, optionally, the semiconductor chip 515. After this, a solder ball 540 may be formed in each of the open regions of the insulating layer 504. Alternatively, a conductive pattern may be formed in place of the solder balls 540.

As illustrated in FIG. 4, the package structure may be bonded to another package structure having the same configuration such that conductive members of first package structure are in contact with corresponding studs or a conductive members of another package structure.

As explained above, to the exemplary embodiments of the present invention provide an enclosure body formed on the entire surface of a conductive substrate on which a semiconductor chip is mounted with conductive studs installed in the enclosure body outside the periphery of the semiconductor chip. This construction does not require solder balls having heights greater than of the semiconductor chip or enclosing body, allowing a semiconductor package to be formed using small-sized solder balls or no solder balls at all. Accordingly, the height of the resulting multi-chip semiconductor package can be decreased. Also, because a chip and studs can be formed within an enclosure body, the misalignment margin can be reduced, allowing highly integrated packages having reduced surface area to be constructed.

Further, because the enclosure body is formed on the entire surface of the substrate, the load applied to a particular portion of the substrate can be reduced. Thus, the mechanical strength of the semiconductor package can be enhanced and a thinner substrate can be used. And, because the enclosure body is formed on the entire surface of a substrate, the alignment margin of the conventional process is not required, allowing additional reductions in the size of the resulting multi-chip semiconductor package.

While the present invention has been particularly shown and described with reference to certain exemplary embodiments, it will be understood by those of ordinary skill in the art that various changes in form and details may be made therein without departing from the spirit and scope of the present invention as defined by the following claims.

What is claimed is:

1. A multi-chip semiconductor package comprising:
a plurality of stacked semiconductor package structures, each semiconductor package structure including;
a substrate having an upper surface and a lower surface;
a semiconductor chip mounted on the substrate, the semiconductor chip including an active surface and a backside surface;
an enclosure body covering substantially the entire upper surface of the substrate;
a plurality of conductive studs extending through the enclosure body outside a periphery of the semiconductor chip, the conductive studs having an upper surface and a lower surface; and
at least one conductive member formed in contact with the lower surface of at least one of the conductive studs.

2. A multi-chip semiconductor package according to claim 1, wherein:
the stacked semiconductor package structures include an upper package structure and a lower package structure, the upper package structure and the lower package structure having substantially the same configuration;
wherein the at least one conductive member of the upper package structure is in electrical contact with at least one conductive stud of the lower package structure.

3. A multi-chip semiconductor package according to claim 1, wherein:
the stacked semiconductor package structures include an upper package structure and a lower package structure, the upper package structure and the lower package structure having substantially the same configuration;
wherein the at least one conductive member of the upper package structure is in direct electrical contact with the at least one conductive member of the lower package structure.

4. A multi-chip semiconductor package according to claim 1, wherein:
the substrate includes
a conductive layer, the conductive layer having an upper surface and a lower surface, and
an insulating layer, the insulating layer being formed on the lower surface on the conductive layer.

5. A multi-chip semiconductor package according to claim 4, wherein:
the active surface of the semiconductor chip includes conductive pads, the conductive pads being electrically connected to the conductive layer.

6. A multi-chip semiconductor package according to claim 5, wherein:
backside surface of the semiconductor chip is recessed below a plane defined by the upper surface of the conductive layer.

7. A multi-chip semiconductor package according to claim 6, wherein:
the active surface of the semiconductor chip is substantially coplanar with or recessed below the plane defined by the upper surface of the conductive layer.

8. A multi-chip semiconductor package according to claim 5, wherein:
conductive balls are formed on a plurality of bond pads on the active surface of each semiconductor chip, the conductive balls providing direct electrical contact to the conductive layer.

9. A multi-chip semiconductor package according to claim 1, wherein:
the at least one conductive member includes a plurality of solder balls.

10. A multi-chip semiconductor package according to claim 1, wherein:
the at least one conductive member includes a conductive pattern.

11. A multi-chip semiconductor package according to claim 1, wherein:
the substrate includes conductive layer, the conductive layer having an upper surface and a lower surface, and an insulating layer formed on the upper surface of the conductive layer;
and further wherein
a second plurality of conductive studs extend through the insulating layer and are electrically connected to corresponding ones of the plurality of conductive studs extending through the enclosure body.

12. A multi-chip semiconductor package comprising:
an upper semiconductor package structure and a lower semiconductor package structure, each semiconductor package structure including;
a substrate having an upper surface and a lower surface and including a conductive layer and an insulating layer;
a semiconductor chip mounted on the substrate, the semiconductor chip including an active surface and a backside surface;
an enclosure body covering substantially the entire upper surface of the substrate;
a plurality of conductive studs extending through the enclosure body outside a periphery of the semiconductor chip, the conductive studs having an upper surface and a lower surface;
wherein
at least one conductive member is formed in contact with the lower surface of at least one of the conductive studs of the upper semiconductor package structure; and
the upper semiconductor package structure and the lower semiconductor package structure are positioned so that the at least one conductive member is in electrical contact with the upper surface of at least one conductive stud of the lower semiconductor package structure.

13. A multi-chip semiconductor package according to claim 12, wherein:
the at least one conductive member includes a plurality of solder balls formed on the lower surfaces of a plurality of the conductive studs of the upper semiconductor package structure; and
the plurality of solder balls are in electrical contact with the upper surfaces of corresponding conductive studs of the lower semiconductor package structure.

14. A multi-chip semiconductor package according to claim 12, wherein:
the semiconductor chip is mounted in a recessed orientation in which the backside surface lies below a plane defined by the upper surface of the substrate.

15. A multi-chip semiconductor package according to claim 12, wherein:
the insulating layer includes a resin material and the conductive layer includes a metallic material.

16. A method of manufacturing a multi-chip semiconductor package comprising:
providing a substrate, the substrate having an upper surface and a lower surface;
forming a plurality of conductive studs, the conductive studs extending through the substrate;
mounting a semiconductor chip on the upper surface of the substrate;
forming an enclosure body encapsulating the upper surface of the substrate, the semiconductor chip and the conductive studs;
removing an upper portion of the enclosure body to expose an upper surface of the conductive studs;
forming a conductive member on a portion of the lower surface of the substrate in electrical contact with the conductive studs to complete a semiconductor package structure; and
mounting a plurality of stacked semiconductor package structures so that the conductive member of an upper semiconductor package structure is in electrical contact with a lower semiconductor package structure.

17. A method of manufacturing a multi-chip semiconductor package according to claim 16, wherein:
the conductive member of the upper semiconductor package structure is in electrical contact with conductive studs of the lower semiconductor package structure.

18. A method of manufacturing a multi-chip semiconductor package according to claim 16, wherein:
the conductive member of the upper semiconductor package structure is in electrical contact with conductive member of the lower semiconductor package structure.

19. A method of manufacturing a multi-chip semiconductor package according to claim 16, wherein:
providing the substrate includes:
forming conductive layer, the conductive layer having an upper surface and a lower surface;
forming an insulating layer on the lower surface of the insulating layer; and
removing portions of the insulating layer, the removed portions corresponding to locations of the conductive studs.

20. A method of manufacturing a multi-chip semiconductor package according to claim 19, wherein:
the insulating layer is a resin layer; and
the portions of the insulating layer are removed after forming the conductive studs.

21. A method of manufacturing a multi-chip semiconductor package according to claim 1 comprising:
forming the plurality of semiconductor package structures, each semiconductor package structure being formed by
preparing the substrate;
forming the plurality of conductive studs on the substrate, the conductive studs extending through the substrate;
mounting the semiconductor chip on the substrate;
forming electrical connections between the active surface of the semiconductor chip and the upper surface of the substrate on which the semiconductor chip is mounted;
forming the enclosure body encapsulating the upper surface of the substrate, the semiconductor chip, the electrical connections and the conductive studs;
removing an upper portion of the enclosure body to expose the upper surface of the conductive studs; and
forming the conductive member on the lower surface of the substrate, the conductive member being in electrical contact with the lower surface of at least one of the conductive studs; and
stacking an upper semiconductor package structure and a lower semiconductor package structure whereby the conductive member of the upper semiconductor package structure is in electrical contact with a corresponding conductive stud on the lower semiconductor package structure.
